(19) United States
(12) Patent Application Publication
(10) Pub. No.: US 2009/0124096 A1
(43) Pub. Date: May 14, 2009

(54) METHOD OF FABRICATING FLASH MEMORY DEVICE

(75) Inventors: Jae Hyoung Koo, Seoul (KR); Kwon Hong, Seongnam-si (KR); Jae Hong Kim, Seongnam-si (KR); Eun Shil Park, Namyangju-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/164,011

(22) Filed: Jun. 28, 2008

(30) Foreign Application Priority Data
Nov. 12, 2007 (KR) 2007-115003

(51) Int. Cl. H01L 21/31

(52) U.S. Cl. 438/776; 257/E21.24

(57) ABSTRACT

The present invention relates to a method of fabricating a flash memory device, the method of the present invention comprises the steps of forming a tunnel insulating layer on a semiconductor substrate through a plasma oxidation process and performing a nitridation treatment to a surface of the tunnel insulating layer.

### CROSS-REFERENCE TO RELATED APPLICATIONS

This application claims priority from Korean Patent Application No. 10-2007-0115003, filed on Nov. 12, 2007, the contents of which are incorporated herein by reference in its entirety.

### BACKGROUND OF THE INVENTION

The present invention relates to a method of fabricating a flash memory device, and more particularly, to a method of fabricating a flash memory device, being capable of preventing a characteristic of a tunnel insulating layer from being deteriorated to enhance a reliability of the flash memory device.

A flash memory device is a nonvolatile memory device which can retain the information stored in a memory cell even if the supply of power is stopped and can perform an electrical erase and write operation. Recently, due to structures allowing high integration of the device, the flash memory device has been studied vigorously. A unit cell of such a flash memory cell is formed by stacking sequentially a tunnel insulating layer, a floating gate, a dielectric layer and a control gate on an active region of a semiconductor substrate. In the above elements, unlike a gate insulating layer in a conventional transistor, the tunnel insulating layer itself acts as a passage through which the data passes, and so an excellent thin layer characteristic is required for the tunnel insulating layer.

In the NAND type flash memory device, since F-N tunneling is utilized for performing a program operation and an erase operation, if the program and erase operation are repeated numerously, the tunnel insulating layer is deteriorated so that a function of the tunnel insulating layer can not be executed fast enough. Accordingly, a thickness of the tunnel insulating layer is made thin within the design limits to enhance a program speed characteristic. However, in order to prevent a deterioration of the thin layer characteristic, nitrogen is implanted in the thin layer. In a conventional method for implanting nitrogen into the tunnel insulating layer, a pure silicon oxide (SiO₂) layer is grown by a thermal oxidation process such as a wet oxidation process or a radical oxidation process. Then a subsequent annealing process utilizing dinitrogen monoxide (N₂O) gas, nitric oxide (NO) or ammonia (NH₃) gas is performed. In this method, most of the nitrogen implanted into the tunnel insulating layer is accumulated on an interface between the semiconductor substrate and the silicon oxide (SiO₂) layer to substitute for an interface trap charge generated inevitably on an interface between the semiconductor substrate and the silicon oxide (SiO₂) layer. Consequently, an interface characteristic of the tunnel insulating layer is improved.

However, since the tunnel insulating layer is grown through a wet oxidation process using H₂O at a high temperature of 800° C. or more or through a radical oxidation process using H₂ and O₂ at a high temperature and a low pressure, a hydrogen based defect bond (i.e., a dangling bond) such as silicon-hydrogen (Si—H) bond is generated by an influence of hydrogen to increase the defect charge to be trapped in the tunnel insulating layer into a deep level. This causes reliability problems such as a cycling characteristic and a charge retention characteristic. Further, in the wet oxidation process or the radical oxidation process a high process temperature of 800° C. or more is required so that the thermal budget is increased, causing boron to be diffused out and a quality of the tunnel insulating layer is deteriorated in a subsequent high temperature process.

### SUMMARY OF THE INVENTION

It is a feature of the present invention to provide a method of fabricating a flash memory device, in which a tunnel insulating layer is formed on a semiconductor substrate using a plasma oxidation process and a nitridation treatment is then performed to a surface of the tunnel insulating layer, thereby enhancing a cycling, charge retention and leakage current characteristics of the tunnel insulating layer.

A method of fabricating a flash memory device according to one embodiment of the present invention comprises the steps of forming a tunnel insulating layer on a semiconductor substrate through a plasma oxidation process; and performing a nitridation treatment to a surface of the tunnel insulating layer.

In the above method, the plasma oxidation process utilizes argon (Ar) gas and oxygen (O₂) gas and is performed under a condition of temperature of 200 to 500 ° C., a pressure of 0.1 to 10 Torr and a power of 0 to 5 kW.

The plasma oxidation process utilizes a direct current discharge, a radio-frequency discharge or a microwave to generate plasma. The tunnel insulating layer is formed with a thickness of 20 to 100 Å. The plasma oxidation process comprises the step of adding additionally hydrogen (H₂) gas whose amount is less than 1.0% of the amount of the overall gas to increase a growth ratio of the tunnel insulating layer.

A plasma nitridation treatment process is performed as the nitridation treatment. The plasma nitridation treatment process utilizes argon (Ar) gas and nitrogen (N₂) gas and is performed under a condition of a temperature of 200 to 500° C., a pressure of 0.1 to 10 Torr and a power of 0 to 5 kW. The plasma nitridation treatment process utilizes a direct current discharge, a radio-frequency discharge or a microwave to generate plasma.

An insulating layer is formed on the tunnel insulating layer through the nitridation treatment. At this time, the insulating layer is formed with a thickness of 5 to 20 Å.

In the plasma nitridation treatment process, hydrogen (H₂) gas is additionally added to increase a deposition ratio.

The method of the present invention further comprises the step of accumulating nitrogen on an interface between the semiconductor substrate and the tunnel insulating layer before or after performing the nitridation treatment. In addition, the method of the present invention further comprises the step of accumulating nitrogen on an interface between the semiconductor substrate and the tunnel insulating layer before and after performing the nitridation treatment.

As the step of accumulating nitrogen, an annealing process utilizing dinitrogen monoxide (N₂O) gas or nitric oxide (NO) gas is performed.

The annealing process utilizing dinitrogen monoxide (N₂O) gas is performed under a condition of atmosphere of nitric oxide (NO) or nitrogen (N₂), a temperature of 800 to 950° C. and an atmospheric pressure and utilizes oxygen (O₂) gas for purging a process chamber. The annealing process utilizing dinitrogen monoxide (N₂O) gas is performed in a pre activation chamber.

The annealing process utilizing nitric oxide (NO) gas is performed under a condition of atmosphere of dinitrogen monoxide (N₂O), a temperature of 800 to 950° C. and a normal pressure and utilizes nitrogen (N₂) gas and oxygen (O₂) gas for purging a process chamber.

An insulating layer having a silicon-nitrogen (Si—N) bonding is formed on an interface between the semiconductor substrate and the tunnel insulating layer by the step of accumulating nitrogen.

The method of the present invention further comprises the step of implanting (or providing) oxygen on an interface between the semiconductor substrate and the tunnel insulating layer after performing the step of accumulating nitrogen.

As the step of implanting oxygen, an ozone (O₃) treatment process is performed.

The ozone treatment process is performed under a condition of a temperature of 300 to 600° C. and a flow rate of 100 to 300 g/m³.

20] An insulating layer having a silicon-oxygen-nitrogen (Si—O—N) bonding is formed on an interface between the semiconductor substrate and the tunnel insulating layer through the step of implanting oxygen.

The method of the present invention further comprises the step of performing a nitrogen (N₂) or oxygen (O₂) annealing process for the tunnel insulating layer before performing the nitridation treatment.

### BRIEF DESCRIPTION OF THE DRAWINGS

FIG. 1A to FIG. 1D are sectional views of a flash memory device for illustrating a method of fabricating a flash memory device according to the first embodiment of the present invention.

### DESCRIPTION OF SPECIFIC EMBODIMENTS

Hereinafter, an embodiment of the present invention will be explained in more detail with reference to the accompanying drawings. However, it should be understood that the embodiment of the present invention can be variously modified, a scope of the present invention is not limited to the embodiment described herein, and the embodiment is provided for explaining more completely the present invention to those skilled in the art.

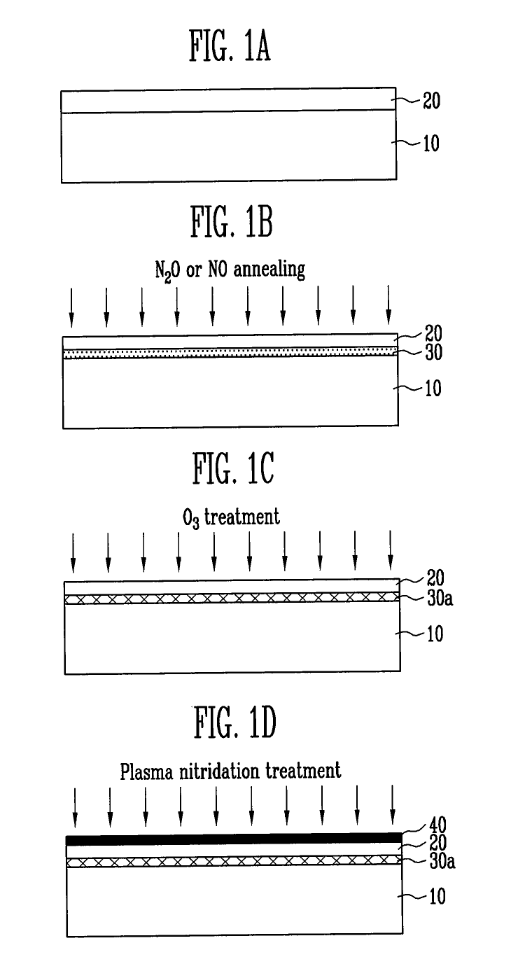

FIG. 1A to FIG. 1D are sectional views of a flash memory device for illustrating a method of fabricating a flash memory device according to the first embodiment of the present invention.

Referring to FIG. 1A, a semiconductor substrate 100 on which a well region (not shown) is formed is provided. The well region may have a triple structure. A screen oxide layer (not shown) is formed on the semiconductor substrate 100, and a well ion implanting process and a threshold voltage ion implanting process are then performed to from the well region having the triple structure.

After the screen oxide layer is removed, a cleaning process can be further performed before forming an insulating layer for forming a tunnel insulating layer on the semiconductor substrate 100 on which the well region is formed. The cleaning process may be performed by using hydrogen fluoride (HF) solution and SC-1 (standard cleaning-1) solution to remove a natural oxide layer and impurities.

Next, a tunnel insulating layer 20 is formed on the semiconductor substrate 100 on which the well region is formed. The tunnel insulating layer can be formed of a silicon oxide (SiO₂) layer. The tunnel insulating layer formed of the silicon oxide layer may be formed through a plasma oxidation process.

The plasma oxidation process can be performed using a processing gas of argon (Ar) gas and oxygen (O₂) gas, a temperature of 200 to 500° C., a pressure of 0.1 to 10 Torr and a power of 0 (zero) to 5 kW. The plasma oxidation process as described is performed by employing a direct current (DC) charge, a radio frequency (RF) discharge or a microwave to generate the plasma. At this time, the tunnel insulating layer 20 may be formed with a thickness of 20 to 100 Å.

Unlike a conventional wet oxidation process and a radical oxidation process for forming a tunnel insulating, if the tunnel insulating layer 20 is formed through the plasma oxidation process utilizing argon (Ar) gas and oxygen (O₂) gas as described above, since it is possible to perform the oxidation process without using hydrogen (H₂), a hydrogen based defect bond (i.e., a dangling bond) such as silicon-hydrogen (Si—H) bond is not generated in the insulating layer 20. This inhibits a generation of a defect charge from being trapped into a deep level. Accordingly, the plasma oxidation process utilizing argon (Ar) gas and oxygen (O₂) gas can reduce the defect charge in the tunnel insulating layer 20 to reduce a threshold voltage shift and can enhance cycling and charge retention characteristics.

In addition, since the tunnel insulating layer 20 is formed by the plasma oxidation process, a more dense thin layer can be obtained so that it is possible to prevent a quality of tunnel insulating layer from being deteriorated in a subsequent high temperature process.

Furthermore, since the tunnel insulating layer 20 is formed at a low temperature of 500° C. or less, it is possible to improve the bird's peak phenomenon meaning that an oxide layer is grown at both end portions of the tunnel insulating layer 20 by a thermal budget and to prevent boron from being diffused out to inhibit a deterioration of the quality of a layer.

As described above, it is preferable not to use hydrogen in the plasma oxidation process performed for forming the tunnel insulating layer 20 so as to prevent the dangling bond from being formed. However, hydrogen (H₂) gas may be used additionally in the plasma oxidation process to increase a growth ratio of the tunnel insulating layer 20. In this case, a small quantity of hydrogen (H₂) gas of 1.0% or less with respect to the amount of overall gas, which is less than the 10% in the conventional method, is added in the plasma oxidation process to minimize a generation of the dangling bond.

Referring to FIG. 1B, a process for accumulating nitrogen on an interface between the semiconductor substrate 10 and the tunnel insulating layer 20 in an in-situ manner is further carried out. At this time, an annealing process utilizing dinitrogen monoxide (N₂O) gas or nitric oxide (NO) gas can be performed as the process for accumulating nitrogen.

In this case, the annealing process utilizing dinitrogen monoxide (N₂O) gas is performed in an atmosphere of dinitrogen monoxide (N₂O), a temperature of 800 to 950° C. and a normal pressure and utilizes nitrogen (N₂) gas and oxygen (O₂) gas for purging a process chamber. At this time, the dinitrogen monoxide (N₂O) annealing process is performed in a pre activation chamber. In the meantime, the annealing process utilizing nitric oxide (NO) gas is performed in an atmosphere of nitric oxide (NO) and nitrogen (N₂), a temperature of 800 to 950° C. and a normal pressure and utilizes oxygen (O₂) gas for purging a process chamber.

According to the above process, nitrogen is substituted for hydrogen in the dangling bond formed on an interface between the semiconductor substrate 10 and the tunnel insulating layer 20, and so a first insulating layer 30 is formed having a silicon-nitrogen (Si—N) bonding. The first insulating layer 30 can be formed of a silicon nitride (Si₃N₄) layer. Thus, a density of an interface trap charge generated inevitably in an interface between the semiconductor substrate 10 and the tunnel insulating layer 20 can be reduced by the first insulating layer 30 having the silicon-nitrogen (Si—N) bonding, and the stress induced leakage current (SILC) and capacitance-voltage (C-V) characteristics can be improved to enhance the cycling and charge retention characteristics of the tunnel insulating layer 20.

Referring to FIG. 1C, a process for implanting oxygen in the first insulating layer 30 in which nitrogen is accumulated, in an in-situ manner, is further performed. The oxygen implantation can be achieved by performing an ozone (O₃) treatment process. In this case, the ozone treatment process may be performed using a temperature of 300 to 600° C. and a flow rate of 100 to 300 g/m³.

Due to the above process, oxygen (O₂) is bonded to the first insulating layer 30 having the silicon-nitrogen (Si—N) bonding, and so the first insulating layer 30 is transformed into a second insulating layer 30a having a silicon-oxygen-nitrogen (Si—O—N) bonding.

At this time, the second insulating layer 30a having the silicon-oxygen-nitrogen (Si—O—N) bonding alleviates an electrical stress and increases the amount of oxygen in the layer. Also, the second insulating layer 30a having the silicon-oxygen-nitrogen (Si—O—N) bonding can improve a surface roughness to enhance a characteristic of the device such as the cycling and charge retention characteristics of the tunnel insulating 20.

In particular, when the annealing process using nitric oxide (NO) is performed, a deterioration of the tunnel insulating layer 20 characteristics caused by a modification of a nitrogen (N) profile can be prevented.

Referring to FIG. 1D, a nitridation treatment is performed for a surface of the tunnel insulating layer 20. A plasma nitridation treatment process is performed as the nitridation treatment. In this case, the plasma nitridation treatment process can utilize argon (Ar) gas and nitrogen (N₂) gas and may be performed using a temperature of 200 to 500° C., a pressure of 0.1 to 10 Torr and a power of 0 to 5 kW. The above plasma nitridation treatment process employs a direct current (DC) discharge, a radio-frequency (RF) discharge or a microwave to generate a plasma. Accordingly, a surface of the tunnel insulating layer 20 is nitrified through the plasma nitridation treatment process so that a third insulating layer 40 containing nitrogen is formed on a surface of the tunnel insulating layer 20. The above third insulating layer 40 may be formed of a silicon nitride (Si₃N₄) layer or a silicon oxynitride (SiON) layer, and can be formed with a thickness of 5 to 20 Å. When the plasma treatment process is performed, on the other hand, hydrogen (H₂) may be utilized additionally to increase a deposition ratio of the third insulating layer 40.

As described, if the nitridation treatment is performed for the tunnel insulating layer 20, a leakage current of the tunnel insulating layer 20 can be reduced to enhance a leakage current characteristic so that a reliability of the device can be enhanced.

The above description illustrates that the plasma nitridation treatment process is performed after the dinitrogen monoxide (N₂O) or nitric oxide (NO) annealing process is completed. After the tunnel insulating layer 20 is formed, however, the plasma nitridation treatment process is performed to form first the third insulating layer 40. The dinitrogen monoxide (N₂O) or nitric oxide (NO) annealing process can then be performed to form the third insulating layer 30.

In addition, after the tunnel insulating layer 20 is formed, the dinitrogen monoxide (N₂O) or nitric oxide (NO) annealing process is performed to form the third insulating layer 30, the plasma nitridation treatment process is then performed to form first the third insulating layer 40, and the dinitrogen monoxide (N₂O) or nitric oxide (NO) annealing process can be further performed additionally for compensating for a concentration of nitrogen in the third insulating layer 30. At this time, the ozone treatment process may be further performed after the dinitrogen monoxide (N₂O) or nitric oxide (NO) annealing process is completed.

In addition, after the tunnel insulating layer 20 is formed, instead of a dinitrogen monoxide (N₂O) or nitric oxide (NO) annealing process, a nitrogen (N₂) or oxygen (O₂) annealing process can be performed to densify the tunnel insulating layer and the plasma nitridation treatment process can be subsequently performed.

Although not shown in the drawings, a polysilicon layer for a floating gate is subsequently formed on the third insulating layer 40, and a subsequent process is then carried out to complete the flash memory device.

The present invention has the following effects.

First, in the present invention, the tunnel insulating layer is formed through the plasma oxidation process in which hydrogen (H₂) is not utilized, but using argon (Ar) gas and oxygen (O₂), and the nitridation treatment is performed to a surface of the tunnel insulating layer so that a generation of the defect charges caused by the dangling bonds such as a silicon-hydrogen (Si—H) bonding is inhibited. This reduces a threshold voltage shift of the device, enhances a cycling characteristic and a charge retention characteristic, and reduces a leakage current to enhance a leakage current characteristic.

Second, since the tunnel insulating layer is formed through the plasma oxidation process, it is possible to obtain a denser thin layer so that a deterioration of the quality of the tunnel insulating layer in a subsequent high temperature process can be prevented.

Third, since the tunnel insulating layer is formed at a temperature of 500° C. or less, a bird's beak phenomenon of the tunnel insulating layer caused by a thermal budget is improved and it is possible to prevent boron from being diffused out to inhibit a quality of the layer from being deteriorated.

Fourth, the annealing process utilizing dinitrogen monoxide (N₂O) gas or nitric oxide (NO) gas is further performed to accumulate nitrogen on an interface between the semiconductor substrate and the tunnel insulating layer for substituting nitrogen for an interface trap charge, and so an interface characteristic of the tunnel insulating layer can be improved.

The ozone (O₃) treatment process is further performed after the annealing process utilizing dinitrogen monoxide (N₂O) gas or nitric oxide (NO) gas to transform the insulating layer having a silicon-nitrogen (Si—N) bonding on an interface of the semiconductor substrate and the tunnel insulating layer into the insulating layer having a silicon-oxygen-nitrogen (Si—O—N) bonding for alleviating the electrical stress of the tunnel insulating layer, increasing a density of oxygen, and enhancing a cycling characteristic and a charge retention characteristics of the tunnel insulating layer through an improvement of surface roughness.

Sixth, a quality of the tunnel insulating layer can be enhanced to enhance the quality of the device.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a flash memory device, the method comprising:
forming a tunnel insulating layer over a semiconductor substrate using a plasma oxidation process; and
performing a nitridation treatment on a surface of the tunnel insulating layer.

2. The method of fabricating a flash memory device of claim 1, wherein the plasma oxidation process utilizes argon (Ar) gas and oxygen (O₂) gas.

3. The method of fabricating a flash memory device of claim 1, wherein the plasma oxidation process is performed at a temperature of 200 to 500° C.

4. The method of fabricating a flash memory device of claim 1, wherein the plasma oxidation process is performed under a pressure of 0.1 to 10 Torr at a power of 0 to 5 kW.

5. The method of fabricating a flash memory device of claim 1, wherein the plasma oxidation process utilizes a direct current discharge, a radio-frequency discharge or a microwave to generate plasma.

6. The method of fabricating a flash memory device of claim 1, wherein the tunnel insulating layer is formed with a thickness of 20 to 100 Å.

7. The method of fabricating a flash memory device of claim 1, wherein the plasma oxidation process comprises:
adding hydrogen (H₂) gas whose amount is less than 1.0% of the amount of the overall gas to increase a growth ratio of the tunnel insulating layer.

8. The method of fabricating a flash memory device of claim 1, wherein the step of performing a nitridation treatment is performed by a plasma nitridation treatment process.

9. The method of fabricating a flash memory device of claim 8, wherein the plasma nitridation treatment process utilizes argon (Ar) gas and nitrogen (N₂) gas under a temperature of 200 to 500° C.

10. The method of fabricating a flash memory device of claim 8, wherein the plasma nitridation treatment process is performed under a pressure of 0.1 to 10 Torr at a power of 0 to 5 kW.

11. The method of fabricating a flash memory device of claim 1, wherein the tunnel insulating layer has an insulating layer formed thereon through the nitridation treatment.

12. The method of fabricating a flash memory device of claim 10, wherein the insulating layer is formed with a thickness of 5 to 20 Å.

13. The method of fabricating a flash memory device of claim 8, wherein the plasma nitridation treatment process comprises the step of adding additionally hydrogen (H₂) gas to increase a deposition ratio.

14. The method of fabricating a flash memory device of claim 1, further comprising the step of accumulating nitrogen at an interface between the semiconductor substrate and the tunnel insulating layer before or after performing the nitridation treatment.

15. The method of fabricating a flash memory device of claim 14, wherein the step of accumulating nitrogen includes an annealing process utilizing dinitrogen monoxide (N₂O) gas or nitric oxide (NO) gas.

16. The method of fabricating a flash memory device of claim 14, wherein the annealing process utilizing dinitrogen monoxide (N₂O) gas is performed under a condition of nitric oxide (NO) or nitrogen (N₂) atmosphere, a temperature of 800 to 950° C. and a normal pressure and utilizes oxygen (O₂) gas for purging a process chamber.

17. The method of fabricating a flash memory device of claim 14, wherein the annealing process utilizing dinitrogen monoxide (N₂O) gas is performed in a pre activation chamber.

18. The method of fabricating a flash memory device of claim 14, wherein the annealing process utilizing nitric oxide (NO) gas is performed under a condition of atmosphere of dinitrogen monoxide (N₂O), a temperature of 800 to 950° C. and a normal pressure and utilizes nitrogen (N₂) gas and oxygen (O₂) gas for purging a process chamber.

19. The method of fabricating a flash memory device of claim 14, wherein an insulating layer having a silicon-nitrogen (Si—N) bonding is formed at an interface between the semiconductor substrate and the tunnel insulating layer by the step of accumulating nitrogen.

20. The method of fabricating a flash memory device of claim 14, further comprising providing oxygen atoms between the semiconductor substrate and the tunnel insulating layer after performing the step of accumulating nitrogen.

21. The method of fabricating a flash memory device of claim 20, wherein the step of providing oxygen is performed by an ozone (O₃) treatment process.

22. The method of fabricating a flash memory device of claim 21, wherein the ozone treatment process is performed under a condition of a temperature of 300 to 600° C. and a flow rate of 100 to 300 g/m³.

23. The method of fabricating a flash memory device of claim 20, wherein an insulating layer having a silicon-oxygen-nitrogen (Si—O—N) bonding is formed between the semiconductor substrate and the tunnel insulating layer through the step of providing oxygen.

24. The method of fabricating a flash memory device of claim 1, further comprising the step of accumulating nitrogen between the semiconductor substrate and the tunnel insulating layer before and after performing the nitridation treatment.

25. The method of fabricating a flash memory device of claim 24, wherein the step of accumulating nitrogen is performed by an annealing process utilizing dinitrogen monoxide (N₂O) gas or nitric oxide (NO) gas.

26. The method of fabricating a flash memory device of claim 25, wherein the annealing process utilizing dinitrogen monoxide (N₂O) gas is performed under a condition of nitric oxide (NO) or nitrogen (N₂) atmosphere, a temperature of 800 to 950° C. and a normal pressure and utilizes oxygen (O₂) gas for purging a process chamber.

27. The method of fabricating a flash memory device of claim 25, wherein the annealing process utilizing dinitrogen monoxide (N₂O) gas is performed in a pre activation chamber.

28. The method of fabricating a flash memory device of claim 25, wherein the annealing process utilizing nitric oxide (NO) gas is performed under a condition of dinitrogen monoxide (N₂O) atmosphere, a temperature of 800 to 950° C. and a normal pressure and utilizes nitrogen (N₂) gas and oxygen (O₂) gas for purging a process chamber.

29. The method of fabricating a flash memory device of claim 24, wherein an insulating layer having a silicon-nitrogen (Si—N) bonding is formed on an interface between the semiconductor substrate and the tunnel insulating layer through the step of accumulating nitrogen.

30. The method of fabricating a flash memory device of claim 24, further comprising the step of providing oxygen at an interface between the semiconductor substrate and the tunnel insulating layer after performing the step of accumulating nitrogen.

31. The method of fabricating a flash memory device of claim 30, wherein the step of providing oxygen is performed by an ozone (O₃) treatment process.

32. The method of fabricating a flash memory device of claim 31, wherein the ozone treatment process is performed under a condition of a temperature of 300 to 600° C. and a flow rate of 100 to 300 g/m³.

33. The method of fabricating a flash memory device of claim 30, wherein an insulating layer having a silicon-oxygen-nitrogen (Si—O—N) bonding is formed at an interface between the semiconductor substrate and the tunnel insulating layer when oxygen is provided.

34. The method of fabricating a flash memory device of claim 1, further comprising the step of performing a nitrogen (N₂) or oxygen (O₂) annealing process for the tunnel insulating layer before performing the nitridation treatment.
